(19) United States
(12) Patent Application Publication
(10) Pub. No.: US 2026/0282603 A1
(43) Pub. Date: Sep. 17, 2026

(54) LIGHT-EMITTING ELEMENT AND DISPLAY DEVICE

(71) Applicant: Sharp Display Technology Corporation, Kameyama City, Mie (JP)

(72) Inventors: Yoji MATSUDE, Sakai City, Osaka (JP); Yukio TAKENAKA, Sakai City, Osaka (JP); YOSHIHIRO UETA, Sakai City, Osaka (JP)

(21) Appl. No.: 19/117,173

(22) PCT Filed: Oct. 6, 2022
(86) PCT No.: PCT/JP2022/037449

§ 371 Date: Mar. 31, 2025

(51) Int. Cl. H10H 20/812; H10H 20/01; H10H 20/823

(52) U.S. Cl. CPC H10H 20/812; H10H 20/012; H10H 20/823

(57) ABSTRACT

A light-emitting element includes an anode, a cathode, and a light-emitting layer provided between the anode and the cathode. The light-emitting layer includes a first portion including an inorganic matrix of a first material and a second portion including an inorganic matrix of a second material. The first portion is provided closer to the anode than the second portion. The first portion includes a plurality of quantum dots including a third material different from the first material and the second material. Filling with at least the inorganic matrix of the first material is made between the plurality of quantum dots. The filling rate of the quantum dots in a cross section of the first portion is greater than the filling rate of the quantum dots in a cross section of the second portion.

### TECHNICAL FIELD

The disclosure relates to a light-emitting element, a display device, and a method for forming a light-emitting layer.

### BACKGROUND ART

In recent years, a quantum dot light emitting diode (QLED) as a light-emitting element including quantum dots and a display device including the QLED have been attracting a lot of attention because power consumption can be lowered, thickness can be reduced, higher picture quality can be achieved, and the like. For such reason, a method for forming a light-emitting layer that includes quantum dots and is provided in a QLED has been actively researched.

For example, PTL 1 describes a QLED including a quantum dot light-emitting layer. In the quantum dot light-emitting layer, a first surface in contact with a hole transport layer and a second surface in contact with an electron transport layer have different organic ligand distributions from each other, that is, a substituted proportion of a plurality of first organic ligands covering a plurality of quantum dots on a first surface side with second organic ligands is different from a substituted proportion of a plurality of first organic ligands covering a plurality of quantum dots on a second surface side with second organic ligands.

### CITATION LIST

### Patent Literature

PTL 1: JP 2010-114079 A

### SUMMARY

### Technical Problem

However, in the QLED described in PTL 1, the plurality of quantum dots included in the quantum dot light-emitting layer are respectively covered with the first organic ligands or the first and second organic ligands, and the quantum dot light-emitting layer cannot suppress the generation of surplus organic ligands. In such a case, due to the influence of the surplus organic ligands, a reactive current increases in the quantum dot light-emitting layer, and thus there arises a problem that the external quantum efficiency (EQE) decreases.

Furthermore, in the QLED described in PTL 1, filling with the quantum dots including the plurality of first organic ligands is uniformly made in a thickness direction of the quantum dot light-emitting layer, and then the plurality of first organic ligands are partially substituted with the second organic ligands, whereby the filling with the quantum dots is uniformly made in the quantum dot light-emitting layer. In the QLED, carrier balancing is often poor due to a fact that the electron mobility in the electron transport layer is higher than the hole mobility in the hole transport layer, and when the quantum dot light-emitting layer is uniformly filled with the quantum dots as described above, there is a problem that it is difficult to improve the carrier balancing.

In addition, the first organic ligands, the second organic ligands, and the surplus organic ligands described in PTL 1 are each an organic ligand, whereby a problem in the reliability also arises because the deterioration caused by energization cannot be suppressed.

An aspect of the disclosure has been made in view of the above-described problems, and an object of the disclosure is to provide a light-emitting element, a display device, and a method for forming a light-emitting layer, in which the external quantum efficiency (EQE), carrier balancing, and reliability are improved.

### Solution to Problem

In order to solve the above-mentioned problems, a light-emitting element of the disclosure includes:
an anode;
a cathode; and
a light-emitting layer provided between the anode and the cathode, wherein
the light-emitting layer includes a first portion including an inorganic matrix of a first material and a second portion including an inorganic matrix of a second material,
the first portion is provided closer to the anode than the second portion,
the first portion includes a plurality of quantum dots different from the first material and the second material,
filling with at least the inorganic matrix of the first material is made between the plurality of quantum dots,
the second portion includes the plurality of quantum dots included in the first portion, and
a filling rate of the plurality of quantum dots in a cross section of the first portion is greater than a filling rate of the plurality of quantum dots in a cross section of the second portion.

In order to solve the problems described above, a display device of the disclosure includes the light-emitting element described above.

In order to solve the above-described problems, a method for forming a light-emitting layer of the disclosure includes:
forming a first portion by using a first solution including a precursor of a first material that forms an inorganic matrix of the first material, a plurality of quantum dots different from the first material, and a first solvent; and
forming a second portion by using a second solution including a precursor of a second material that forms an inorganic matrix of the second material different from the plurality of quantum dots, the plurality of quantum dots, and a second solvent, wherein
the number of the plurality of quantum dots included per unit volume of the second solution is 0 or more and less than the number of the plurality of quantum dots included per unit volume of the first solution.

### Advantageous Effects of Disclosure

According to an aspect of the disclosure, it is possible to provide a light-emitting element, a display device, and a method for forming a light-emitting layer, in which the external quantum efficiency (EQE), carrier balancing, and reliability are improved.

### BRIEF DESCRIPTION OF DRAWINGS

FIG. 1 is a schematic cross-sectional view illustrating a schematic configuration of a light-emitting element according to a first embodiment.

FIG. 2 is a schematic cross-sectional view of a first portion provided in the light-emitting element according to the first embodiment.

FIG. 3 is a schematic cross-sectional view of a second portion provided in the light-emitting element according to the first embodiment.

FIG. 4 is a diagram for explaining a region formed between quantum dots when two quantum dots adjacent to each other among a plurality of the quantum dots included in the first portion illustrated in FIG. 2 or the second portion illustrated in FIG. 3 are arranged close to each other.

FIG. 5 is a diagram for explaining a region formed between quantum dots when two quantum dots adjacent to each other among the plurality of quantum dots included in the first portion illustrated in FIG. 2 or the second portion illustrated in FIG. 3 are arranged slightly separate from each other.

FIG. 6 is a schematic view illustrating band levels of a hole transport layer, a light-emitting layer, and an electron transport layer, which are provided in the light-emitting element according to the first embodiment.

FIG. 7 is a schematic view for explaining an example of steps of introducing a halogen ligand with respect to a quantum dot included in the first portion of the light-emitting layer provided in the light-emitting element according to the first embodiment.

FIG. 8 is a schematic view illustrating a first solution used in a step of forming the first portion of the light-emitting layer provided in the light-emitting element according to the first embodiment.

FIG. 9 is a schematic cross-sectional view illustrating a schematic configuration of a light-emitting element according to a second embodiment.

FIG. 10 is a schematic cross-sectional view of a second portion provided in the light-emitting element according to the second embodiment.

FIG. 11 is a schematic view illustrating band levels of a hole transport layer, a light-emitting layer, and an electron transport layer, which are provided in the light-emitting element according to the second embodiment.

FIG. 12 is a schematic cross-sectional view illustrating a schematic configuration of a display device according to a third embodiment.

### DESCRIPTION OF EMBODIMENTS

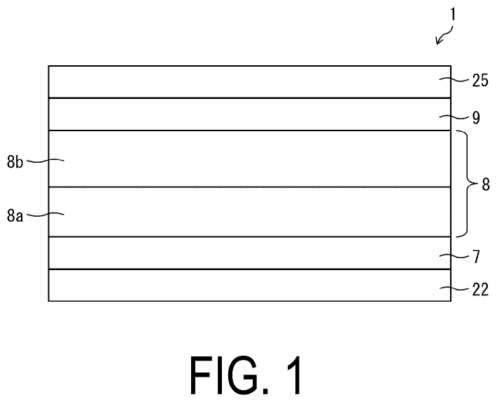

Embodiments of the disclosure will be described below with reference to FIG. 1 to FIG. 12. Hereinafter, for convenience of description, configurations having the same functions as those described in a specific embodiment are denoted by the same reference signs, and descriptions thereof will be omitted.

### First Embodiment

FIG. 1 is a cross-sectional view illustrating a schematic configuration of a light-emitting element 1 according to a first embodiment.

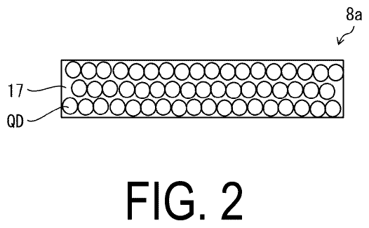

FIG. 2 is a cross-sectional view of a first portion 8a provided in the light-emitting element 1 according to the first embodiment.

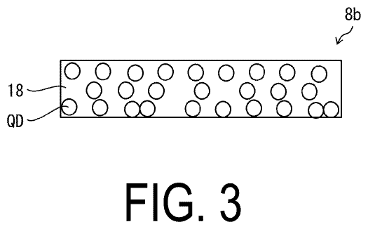

FIG. 3 is a cross-sectional view of a second portion 8b provided in the light-emitting element 1 according to the first embodiment.

As illustrated in FIG. 1, the light-emitting element 1 includes an anode 22, a cathode 25, and a light-emitting layer 8 provided between the anode 22 and the cathode 25.

The light-emitting layer 8 includes the first portion 8a including an inorganic matrix of a first material 17 illustrated in FIG. 2 and the second portion 8b including an inorganic matrix of a second material 18 illustrated in FIG. 3, and the first portion 8a is provided closer to the anode 22 than the second portion 8b.

The matrix means a member that includes and holds other objects, and can be referred to as a base material, a parent material, or a filler. The matrix may be solid at room temperature. The matrix may be a member that includes and holds quantum dots QD. The inorganic matrix may be a member that can include and hold the quantum dots QD, and the disclosure also includes a case in which the quantum dots QD are not evenly distributed in the inorganic matrix. Furthermore, in a certain inorganic matrix region, the presence of an inorganic matrix region including no quantum dot QD is also allowed. The inorganic matrix may be a substance capable of holding the quantum dot or the like, and each inorganic matrix is not necessarily needed to hold the quantum dot QD.

In the present embodiment, as illustrated in FIGS. 2 and 3, a case where each of the inorganic matrix of the first material 17 and the inorganic matrix of the second material 18 is a member including and holding the quantum dots QD will be described as an example, but the disclosure is not limited thereto. For example, as in a second embodiment to be described later, a matrix constituted by the inorganic matrix of the first material 17 and the inorganic matrix of the second material 18 may be a member including and holding the quantum dots QD. Although not illustrated, for example, in at least some quantum dots among a plurality of the quantum dots QD, the inorganic matrix of the first material 17 and the inorganic matrix of the second material 18 may include and hold the same quantum dots QD as in a case where only part of a quantum dot is covered with the inorganic matrix of the first material 17 and the remaining part thereof is covered with the inorganic matrix of the second material 18. Even when only part of the quantum dot QD is covered with the inorganic matrix of the first material 17 or the inorganic matrix of the second material 18, the inorganic matrix of the first material 17 or the inorganic matrix of the second material 18 is a member that contains and holds the quantum dot QD.

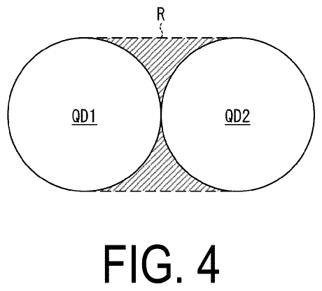

FIG. 4 is a schematic view depicting part of a cross section of the first portion 8a illustrated in FIG. 2 or the second portion 8b illustrated in FIG. 3, for explaining a region R formed between quantum dots QD1 and QD2 when two quantum dots QD1 and QD2 adjacent to each other among the plurality of quantum dots QD included in the first portion 8a illustrated in FIG. 2 or the second portion 8b illustrated in FIG. 3 are arranged close to each other.

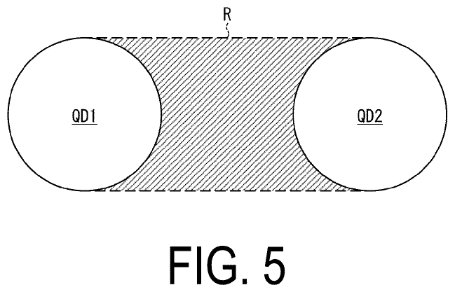

FIG. 5 is a schematic view depicting part of a cross section of the first portion 8a illustrated in FIG. 2 or the second portion 8b illustrated in FIG. 3, for explaining the region R formed between the quantum dots QD1 and QD2 when the two quantum dots QD1 and QD2 adjacent to each other among the plurality of quantum dots QD included in the first portion 8a illustrated in FIG. 2 or the second portion 8b illustrated in FIG. 3 are arranged slightly separate from each other.

When it is recognized that the filling with the inorganic matrix is made between at least two quantum dots QD, the expression “the filling with the inorganic matrix is made between the plurality of quantum dots” is satisfied. The expression “the filling with the inorganic matrix is made between two quantum dots QD” means that the region R depicted in FIGS. 4 and 5 is filled with the inorganic matrix, or two quantum dots QD1 and QD2 adjacent to each other are held due to the presence of the inorganic matrix in the region R. The region R is a region that is surrounded by two straight lines (external common tangents) in contact with the outer peripheries of the two quantum dots QD1 and QD2 adjacent to each other, and the outer peripheries facing each other of the two quantum dots QD1 and QD2 adjacent to each other. Even when the two adjacent quantum dots QD1 and QD2 are arranged close to each other as illustrated in FIG. 4, or even when the two adjacent quantum dots QD1 and QD2 are arranged slightly separate from each other as illustrated in FIG. 5, the region R is present and is filled with the matrix. Note that in the disclosure, at least part of the region R may be filled with the matrix.

In the present embodiment, the case where the region R formed between the two adjacent quantum dots QD1 and QD2 illustrated in FIGS. 4 and 5, i.e., the space between the plurality of quantum dots QD is filled with the inorganic matrix of the first material 17 or the inorganic matrix of the second material 18 will be described as an example, but the disclosure is not limited thereto. For example, part of the region R on a lower side illustrated in FIGS. 4 and 5 may be filled with the inorganic matrix of the first material 17, and part of the region R on an upper side illustrated in FIGS. 4 and 5 may be filled with the inorganic matrix of the second material 18, in such a manner as to form part of the boundary between the first portion 8a and the second portion 8b.

The description that the region R formed between the quantum dots QD1 and QD2 is filled with the matrix may mean that at least part of the region R is buried with the matrix, indicate that the entire region R is filled with the matrix, or indicate that part of the region R is filled with the matrix.

The inorganic matrix of the first material 17 may be formed to fill a region (space) excluding the plurality of quantum dots QD in the first portion 8a of the light-emitting layer 8. As illustrated in FIG. 2, the outer edge of the first portion 8a of the light-emitting layer 8 may be formed with the matrix, and the plurality of quantum dots QD may be formed to be located away from the outer edge. In other words, the inorganic matrix of the first material 17 may embrace the plurality of quantum dots QD. Furthermore, although not illustrated, at least part of the outer edge of the first portion 8a of the light-emitting layer 8 may be formed of the matrix and the quantum dots QD. The plurality of quantum dots QD may be respectively embedded at intervals in the inorganic matrix of the first material 17. Here, the outer edge refers to an upper face and a lower face of the first portion 8a of the light-emitting layer 8.

The inorganic matrix of the second material 18 may be formed to fill a region (space) excluding the plurality of quantum dots QD in the second portion 8b of the light-emitting layer 8. As illustrated in FIG. 3, the outer edge of the second portion 8b of the light-emitting layer 8 may be formed with the matrix, and the plurality of quantum dots QD may be formed to be located away from the outer edge. In other words, the inorganic matrix of the second material 18 may embrace the plurality of quantum dots QD. Furthermore, although not illustrated, at least part of the outer edge of the second portion 8b of the light-emitting layer 8 may be formed of the matrix and the quantum dots QD. The plurality of quantum dots QD may be respectively embedded at intervals in the inorganic matrix of the second material 18. Here, the outer edge refers to an upper face and a lower face of the second portion 8b of the light-emitting layer 8.

The inorganic matrix of the first material 17 may include a continuous film having an area equal to or larger than 1000 nm² along a plane direction orthogonal to a layer thickness direction of the first portion 8a of the light-emitting layer 8, and the inorganic matrix of the second material 18 may include a continuous film having an area equal to or larger than 1000 nm² along the plane direction orthogonal to the layer thickness direction of the second portion 8b of the light-emitting layer 8. The continuous film means a film not partitioned by a material other than a material constituting the continuous film in one plane. The continuous film may be in the form of an integrated film connected without interruption, by chemical bonding of the material constituting the matrix.

The inorganic matrix of the first material 17 and the inorganic matrix of the second material 18 may each be the same material as that of a shell of the quantum dot QD. In this case, an average distance between cores of the adjacent quantum dots QD (core-to-core distance) may be preferably equal to or greater than 3 nm, or equal to or greater than 5 nm. Alternatively, the average distance between the cores of the adjacent quantum dots QD may be preferably 0.5 times or more the average core diameter of the quantum dot QD. The average distance between the cores of the adjacent quantum dots QD (core-to-core distance) is obtained by averaging the distances between 20 adjacent cores in a space including the 20 cores. The average distance between the cores (core-to-core distance) may preferably be maintained wider than the distance between the cores when the shells are in contact with each other. The average core diameter of the quantum dots QD is obtained by averaging the core diameters of 20 quantum dots QD in cross-sectional observation in a space including the 20 quantum dots QD. The core diameter of the quantum dot QD may be the diameter of a circle having the same area in size as a core area of the quantum dot QD in the cross-sectional observation.

The light-emitting layer 8 illustrated in FIG. 1 may be constituted of the plurality of quantum dots QD, and matrices serving as the inorganic matrix of the first material 17 and the inorganic matrix of the second material 18. The intensity of carbon detected by the chain structure of carbon when the light-emitting layer 8 is analyzed may be equal to or less than a noise level.

In each of the inorganic matrix of the first material 17, the inorganic matrix of the second material 18, and the quantum dots QD different from the first material 17 and the second material 18, the band gap of the first material 17 and the band gap of the second material 18 are desirably equal to or larger than the band gap of the quantum dots QD.

As a material constituting the inorganic matrix of the first material 17 and the inorganic matrix of the second material 18, a semiconductor or an insulator can be used. Examples of the constituent materials of the inorganic matrix of the first material 17 and the inorganic matrix of the second material 18 include metal sulfide and/or metal oxide. The metal sulfide may be, for example, zinc sulfide (ZnS), zinc magnesium sulfide (ZnMgS, ZnMgS₂), gallium sulfide (GaS, Ga₂S₃), zinc tellurium sulfide (ZnTeS), magnesium sulfide (MgS), zinc gallium sulfide (ZnGa₂S₄), and magnesium gallium sulfide (MgGa₂S₄). The metal oxide may be, for example, zinc oxide (ZnO), titanium oxide (TiO₂), tin oxide (SnO₂), tungsten oxide (WO₃), and zirconium oxide (ZrO₂). Note that a chemical formula written within parentheses after a compound name is a representative example. In addition, the composition ratio described in the chemical formula is desirably stoichiometry in which the actual composition of the compound is the same as the chemical formula but is not necessarily stoichiometry.

The structure of the matrix described above need not be observed over the entirety of the light-emitting layer 8 as long as the structure described above is recognized by observing a cross section of the light-emitting layer 8 in a range of about 100 nm in width, unless otherwise noted or being inconsistent. The above-described matrix may contain a substance different from the main material (e.g., an inorganic substance such as an inorganic semiconductor) as an additive, for example.

In the present embodiment, a case where a hole transport layer 7 is provided as a hole function layer between the anode 22 and the first portion 8a and an electron transport layer 9 is provided as an electron function layer between the cathode 25 and the second portion 8b will be described as an example, but the disclosure is not limited thereto. It is sufficient for the hole function layer to include at least one of the hole transport layer 7 and a hole injection layer, and it is sufficient for the electron function layer to include at least one of the electron transport layer 9 and an electron injection layer. At least one of the hole function layer and the electron function layer may be appropriately omitted.

As illustrated in FIG. 2, the first portion 8a of the light-emitting layer 8 includes the inorganic matrix of the first material 17 and the plurality of quantum dots QD different from the first material 17 and the second material 18. As illustrated in FIGS. 1 and 2, the first portion 8a of the light-emitting layer 8 is a layer constituting part of the light-emitting layer 8, and is a portion provided closer to the anode 22 than the second portion 8b as described above.

As illustrated in FIG. 3, the second portion 8b of the light-emitting layer 8 includes the inorganic matrix of the second material 18 and the plurality of quantum dots QD different from the first material 17 and the second material 18. As illustrated in FIGS. 1 and 3, the second portion 8b of the light-emitting layer 8 is a layer constituting another part of the light-emitting layer 8, and is a portion provided closer to the cathode 25 than the first portion 8a as described above.

As described above, the light-emitting layer 8 includes the quantum dots QD and the inorganic matrix, with which the filling is made between the quantum dots QD. By doing so, it is unnecessary to hold or cover the quantum dot QD with an organic ligand, and it is possible to prevent the generation of surplus organic ligands. Accordingly, it is possible to prevent a reactive current due to the influence of the surplus organic ligands, thereby making it possible to improve the external quantum efficiency (EQE). The organic ligand cannot suppress the deterioration caused by energization and has a problem in the reliability. However, being the inorganic matrix, the reliability can also be improved.

The filling rate of the quantum dots QD in the cross section of the first portion 8a of the light-emitting layer 8 illustrated in FIG. 2 is larger than the filling rate of the quantum dots QD in the cross section of the second portion 8b of the light-emitting layer 8 illustrated in FIG. 3.

In the present embodiment, a case where the second portion 8b of the light-emitting layer 8 includes the quantum dots QD will be described as an example, but the disclosure is not limited thereto. The second portion 8b of the light-emitting layer 8 may be constituted of the inorganic matrix of the second material 18 without including the quantum dots QD as in the second embodiment to be described later.

Each of the filling rate of the quantum dots QD in the cross section of the first portion 8a and the filling rate of the quantum dots QD in the cross section of the second portion 8b can be obtained from, for example, a transmission electron microscope (TEM) image or a scanning electron microscope (SEM) image, where the cross section of the light-emitting element 1 illustrated in FIG. 1 is enlarged with a predetermined magnification. The predetermined magnification is preferably set in such a manner that a region occupied by the quantum dots QD can be easily distinguished from a region occupied by the inorganic matrix of the first material 17 or the inorganic matrix of the second material 18 in the TEM image or the SEM image, and wider regions of the first portion 8a and the second portion 8b are reflected in the images. For example, in order for the wider regions of the first portion 8a and the second portion 8b to be reflected in the images, a magnification with which the lateral width of the image becomes 640 nm may be selected. The analysis result by the TEM image has priority over the analysis result by the SEM image.

In the images mentioned above, the area of a region occupied by the quantum dots QD or a region occupied by the inorganic matrix of the first material 17 in the cross section of the first portion 8a, and the area of a region occupied by the quantum dots QD or a region occupied by the inorganic matrix of the second material 18 in the cross section of the second portion 8b can be obtained by, for example, performing image processing on the images.

In the present embodiment, as illustrated in FIGS. 1, 2, and 3, a case where a boundary between the first portion 8a and the second portion 8b is formed in direct contact with each other will be described as an example. Further, a case where the inorganic matrix of the first material 17 and the inorganic matrix of the second material 18 are formed in direct contact with each other will be described as an example. In such cases, when the first material 17 and the second material 18 are different materials, and the first material 17 and the second material 18 can be distinguished from each other in the images, it is sufficient to respectively obtain the filling rate of the quantum dots QD in the cross section of the first portion 8a and the filling rate of the quantum dots QD in the cross section of the second portion 8b. The filling rate of the quantum dots QD in the cross section of the first portion 8a can be obtained from a formula of (total area of the quantum dots QD in the cross-section of the first portion 8a×100)/(20 nm×640 nm) or a formula of ((20 nm×640 nm−total area of the inorganic matrix of the first material 17 in the cross-section of the first portion 8a)×100)/(20 nm×640 nm) in a case where the thickness of the first portion 8a is 20 nm and the magnification with which the lateral width of the image becomes 640 nm is selected. The filling rate of the quantum dots QD in the cross section of the second portion 8b can be obtained from a formula of (total area of the quantum dots QD in the cross-section of the second portion 8b×100)/(20 nm×640 nm) or a formula of ((20 nm×640 nm−total area of the inorganic matrix of the second material 18 in the cross-section of the second portion 8b)×100)/(20 nm×640 nm) in a case where the thickness of the second portion 8b is 20 nm and the magnification with which the lateral width of the image becomes 640 nm is selected. In the above description, the method of calculating the filling rate has been described in which the lateral width is the lateral width of the image and a longitudinal width is the thickness of the first portion 8a or the second portion 8b, but the lateral width and the longitudinal width are not necessarily required to be set as described above. It is sufficient that a filling rate in a range of at least 200 nm for the lateral width and 10 nm for the longitudinal width is calculated. However, in a case where the calculation cannot be effectively made in the range of 10 nm for the longitudinal width such as when the entire thickness of the first portion 8a or the second portion 8b is less than 10 nm, the filling rate may be calculated by the height when a maximum-range rectangle is defined in the first portion 8a or the second portion 8b.

There is a first case where the first material 17 and the second material 18 are the same material and the first material 17 and the second material 18 cannot be distinguished from each other in the image discussed above. Furthermore, even when the first material 17 and the second material 18 are different materials, there is a second case where the first material 17 and the second material 18 cannot be distinguished from each other in the image. In the first case and the second case described above, it is sufficient that the first portion 8a and the second portion 8b are defined in a range of at least 200 nm for the lateral width and 10 nm for the longitudinal width, and then the respective filling rates are calculated. In a case where the thickness of the first portion 8a or the second portion 8b cannot be secured to be 10 nm because of the thickness of the light-emitting layer 8 being less than 20 nm or the like, it is sufficient that the light-emitting layer 8 is divided into two rectangles each having half the thickness of the light-emitting layer 8, the rectangle provided near the anode 22 is defined as the first portion 8a, the rectangle provided near the cathode 25 is defined as the second portion 8b, and the filling rate of the quantum dots QD in the cross section of the first portion 8a and the filling rate of the quantum dots QD in the cross section of the second portion 8b are obtained as described above. When a quantum dot QD protruding from the rectangle is present, the protruding portion is not included in the calculation of the filling rate. That is, in the analysis image, it is necessary to calculate the filling rate from the area of the portion of each quantum dot QD included in the rectangle and the area of the matrix.

In the present embodiment, as illustrated in FIGS. 1, 2, and 3, the case in which the light-emitting layer 8 includes two portions having different concentrations of the quantum dots QD, i.e., the first portion 8a and the second portion 8b has been described, but the disclosure is not limited thereto. For example, the light-emitting layer 8 may be constituted of three or more portions having different concentrations of the quantum dots QD. As discussed above, in the case where the light-emitting layer 8 is constituted of three or more portions having different concentrations of the quantum dots QD, it is sufficient that the light-emitting layer 8 is divided into two rectangles each having half the thickness of the light-emitting layer 8, the rectangle provided near the anode 22 is defined as the first portion 8a, the rectangle provided near the cathode 25 is defined as the second portion 8b, and the filling rate of the quantum dots QD in the cross section of the first portion 8a and the filling rate of the quantum dots QD in the cross section of the second portion 8b are obtained as described above.

In general, in a light-emitting element including an anode for supplying holes, a cathode for supplying electrons, and a light-emitting layer, the carrier balancing is often poor because the electron mobility is higher than the hole mobility. In the light-emitting element 1 according to the present embodiment, as described above, the filling rate of the quantum dots QD in the cross section of the first portion 8a of the light-emitting layer 8 is higher than the filling rate of the quantum dots QD in the cross section of the second portion 8b of the light-emitting layer 8, and thus the concentration of the quantum dots QD in the first portion 8a of the light-emitting layer 8 is higher than the concentration of the quantum dots QD in the second portion 8b of the light-emitting layer 8. Accordingly, a larger number of holes H supplied from the anode 22 through the hole transport layer 7 are trapped by a larger number of quantum dots QD contained in the first portion 8a of the light-emitting layer 8 located closer to the anode 22. On the other hand, a larger number of electrons E supplied from the cathode 25 through the electron transport layer 9 are trapped by the larger number of quantum dots QD contained in the first portion 8a of the light-emitting layer 8 located farther from the cathode 25 than by a smaller number of quantum dots QD contained in the second portion 8b of the light-emitting layer 8 located closer to the cathode 25. As a result, a larger number of light emission re-combinations occur in a region on the anode 22 side of the light-emitting layer 8. Thus, imbalance of the mobilities such that the mobility of the electron is higher than the mobility of the hole may be improved by making the arrival speed of the hole H into the light emission re-combination region faster by setting the portion where a larger number of light emission re-combinations occur to be on the anode 22 side.

In the light-emitting element 1 according to the present embodiment, the filling rate of the quantum dots QD in the cross section of the first portion 8a is preferably in a range from 30% to 91%. As described above, by setting the concentration of the quantum dots QD in the first portion 8a of the light-emitting layer 8 to be equal to or higher than a certain amount, it is possible to suppress a situation in which the carrier balancing becomes poor due to a shortage of low-mobility holes. When the filling rate is 91%, quantum dots QD each having a spherical shape are most closely packed.

In the light-emitting element 1 according to the present embodiment, when the second portion 8b of the light-emitting layer 8 includes the quantum dots QD, the filling rate of the quantum dots QD in the cross section of the second portion 8b of the light-emitting layer 8 may be more than 0% and less than 30%, or more than 0% and equal to or less than 20%. As described above, by setting the concentration of the quantum dots QD in the second portion 8b of the light-emitting layer 8 to be less than a certain amount, it is possible to suppress a situation in which the carrier balancing becomes poor due to high-mobility electrons being excessively present.

In the light-emitting element 1 according to the present embodiment, a difference between the filling rate of the quantum dots QD in the cross section of the first portion 8a of the light-emitting layer 8 and the filling rate of the quantum dots QD in the cross section of the second portion 8b of the light-emitting layer 8 is preferably in a range from 10% to 91%. As described above, by securing the difference in the filling rate to be equal to or greater than a certain value, it is possible to secure the improvement in carrier balancing at a certain level or more.

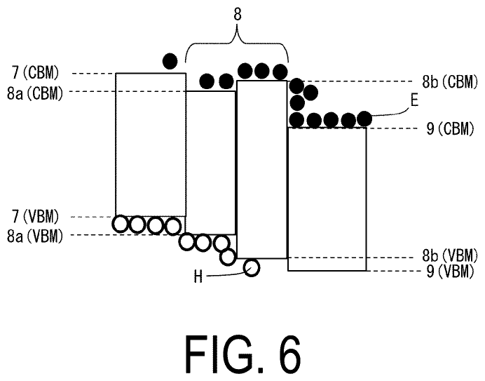

FIG. 6 is a diagram illustrating band levels of the hole transport layer 7, the light-emitting layer 8, and the electron transport layer 9, which are provided in the light-emitting element 1 according to the first embodiment.

In the present embodiment, a case where the band gap of the first material 17 and the band gap of the second material 18 are larger than the band gap of the quantum dot QD will be described as an example, but the disclosure is not limited thereto, and the band gap of the first material 17 and the band gap of the second material 18 may be equal to or larger than the band gap of the quantum dot QD.

As described above, in the case where the band gap of the first material 17 and the band gap of the second material 18 are larger than the band gap of the quantum dot QD and when the filling rate of the quantum dots QD in the cross section of the first portion 8a of the light-emitting layer 8 is larger than the filling rate of the quantum dots QD in the cross section of the second portion 8b of the light-emitting layer 8, it can be schematically represented that the valence band maximum (VBM) of the second portion 8b is deeper than the valence band maximum (VBM) of the first portion 8a and the conduction band minimum (CBM) of the second portion 8b is shallower than the conduction band minimum (CBM) of the first portion 8a as illustrated in FIG. 6. In the light-emitting element 1 as discussed above, since the injection barrier of the electrons E into the light-emitting layer 8 can be made high while suppressing a situation in which the injection barrier of the holes H into the light-emitting layer 8 becomes high, the injection of the electrons E into the light-emitting layer 8 is suppressed, and the overflow of the electrons E into the hole transport layer 7 can be reduced. Accordingly, the life of the light-emitting element 1 can be extended and the reliability of the light-emitting element 1 can be improved.

Each of the first material 17 and the second material 18 included in the light-emitting layer 8 provided in the light-emitting element 1 according to the present embodiment may be a metal sulfide. In the present embodiment, a case where the first material 17 and the second material 18 are made of the same metal sulfide (e.g., ZnS) will be described as an example, but the disclosure is not limited thereto, and the first material 17 and the second material 18 may be different metal sulfides.

Examples of the metal sulfide include a metal sulfide composed of zinc (Zn) and sulfur(S) (e.g., ZnS), a metal sulfide composed of zinc (Zn), tellurium (Te), and sulfur (S) (e.g., ZnTeS), a metal sulfide composed of zinc (Zn), magnesium (Mg), and sulfur(S) (e.g., ZnMgS₂), a metal sulfide composed of magnesium (Mg) and sulfur (S) (e.g., MgS), a metal sulfide composed of gallium (Ga) and sulfur (S) (e.g., Ga₂S₃), a metal sulfide composed of zinc (Zn), gallium (Ga), and sulfur (S) (e.g., ZnGa₂S₄), and a metal sulfide composed of magnesium (Mg), gallium (Ga), and sulfur (S) (e.g., MgGa₂S₄). However, the disclosure is not limited thereto.

The quantum dots QD different from the first material 17 and second material 18 included in the light-emitting layer 8 provided in the light-emitting element 1 according to the present embodiment may have, for example, a core structure, a core/shell structure, a core/shell/shell structure, or a core/shell structure with a continuously varied proportion of the shell. Note that the shell may completely cover the core, or may partially cover the core. A core can be composed of, for example, Si or C in a case of a unitary system, composed of, for example, CdSe, CdS, CdTe, InP, GaP, InN, ZnSe, ZnS, or ZnTe in a case of a binary system, composed of, for example, CdSeTe, GaInP, or ZnSeTe in a case of a ternary system, and composed of, for example, AgInGaS (AIGS) in a case of a quaternary system. A shell can be composed of, for example, CdS, CdTe, CdSe, ZnS, ZnSe, or ZnTe in a case of a binary system, and composed of, for example, CdSSe, CdTeSe, CdSTe, ZnSSe, ZnSTe, ZnTeSe, or AgInP (AIP) in a case of a ternary system.

Since it is sufficient for the quantum dot QD to be different from the first material 17 and the second material 18, in a case where the first material 17 and the second material 18 are each made of ZnS, which is the same metal sulfide, as in the present embodiment, it is sufficient for the core of the quantum dot QD to be composed of a material other than ZnS when the quantum dot QD is made of only the core, or at least one of the core and the shell of the quantum dot QD to be composed of a material other than ZnS when the quantum dot QD includes the core and the shell. Therefore, for example, as in the present embodiment, in the case where each of the first material 17 and the second material 18 is made of ZnS, which is the same metal sulfide, and the core of the quantum dot QD is made of InP, the shell may include ZnS. In other words, when the core is different from the first material 17 and the second material 18, the sell may be made of the same material as the first material 17 and the second material 18. When the shell is made of the same material as the first material 17 and the second material 18, the boundary between the shell and the first material 17 and second material 18 is unknown or substantially unknown. Therefore, it is unknown whether the quantum dot QD has a core/shell structure or has a structure of only the core. However, as long as the quantum dot QD is used in a light-emitting element, it is clear that the quantum dot QD emits light as a result of barrier formation in the periphery even when the quantum dot QD is a core, that is, a single crystal. Accordingly, the quantum dot QD is not necessarily needed to be a material having a quantum confinement effect by itself. The quantum dot QD may be allowed to be a single crystal as long as it is used in the light-emitting element as a result.

As described above, for example, when the core of the quantum dot QD is made of InP, that is, when the core of the quantum dot QD includes indium (In) as an element of a first kind, each of the first material 17 and the second material 18 contains sulfur (S), which is an element of a second kind that is higher by one or more periods than indium (In) as the element of the first kind.

The light-emitting layer 8 provided in the light-emitting element 1 preferably includes an inorganic ligand, for example, a halogen ligand that contains a halogen atom. In a case where the light-emitting layer 8 includes an organic ligand, a value of (A/B)×100% is preferably 15% or less, and more preferably 10% or less, where A is the weight of the organic ligands included in the light-emitting layer 8 measured by thermogravimetry, and B is the weight of the light-emitting layer 8 measured by the thermogravimetry.

Since the organic ligand has a significantly low carrier mobility (10⁻⁶ cm²/V·sec order or less), when the light-emitting layer 8 includes the organic ligands in an amount of more than 15% by the above-mentioned weight percent, the light-emitting layer 8 has a problem that a reactive current flowing through the organic ligands increases. The reactive current flowing through the organic ligand is a non-ohmic current called a space charge limited current (SCLC) and is proportional to the square of the voltage. Accordingly, as described above, the light-emitting layer 8 preferably includes the organic ligands in an amount of 15% or less by the weight percent, and more preferably in an amount of 10% or less by the weight percent.

The organic ligand has a function of protecting the surface of the quantum dot QD. In the present embodiment, the surface of the quantum dot QD can be protected by the inorganic matrix of the first material 17 and the inorganic matrix of the second material 18, and the surface of the quantum dot QD can also be protected by the inorganic ligand. For this reason, in the present embodiment, the surface of the quantum dot QD can be protected even when the light-emitting layer 8 includes the organic ligands in an amount of 15% or less by weigh percent, and also in an amount of 10% or less by weight percent.

In the present embodiment, as compared with the case of the organic ligand discussed above, an inorganic ligand as a material having high carrier mobility such as a halogen ligand containing a halogen atom, and the first material 17 and second material 18 formed of ZnS are used. This makes it possible to reduce the reactive current flowing through in the light-emitting layer 8 and achieve the light-emitting element 1 with the improved external quantum efficiency (EQE).

As described above, the organic ligand has a demerit of generating a reactive current because of having a significantly low carrier mobility, but has a function of protecting the surface of the quantum dot QD and a function of dispersing the quantum dots QD in a solvent. Therefore, the organic ligands may be preferably included in the light-emitting layer 8 in an amount of 15% or less by weight percent, and more preferably in an amount of 10% or less by weight percent.

When the amount of the organic ligands included in the light-emitting layer 8 is made to be preferably 15% or less by weight percent, and more preferably 10% or less by weight percent, and the light-emitting layer 8 is formed using an inorganic ligand, e.g., a halogen ligand containing a halogen atom, and the first material 17 and second material 18 made of ZnS, process tolerability of the light-emitting layer 8 can be improved, whereby the forming process of the light-emitting layer 8 can be made to be a process carried out in the atmosphere so as to achieve a cost reduction.

In the light-emitting layer 8, the above-described inorganic ligand or organic ligand is disposed on the surface of the quantum dot QD or near the surface of the quantum dot QD.

Note that the quantum dot QD means a dot having a maximum width of 100 nm or less. The shape of the quantum dot QD is not particularly limited as long as it is within a range satisfying the above maximum width, and the shape is not limited to a spherical three-dimensional shape (circular cross-sectional shape). The shape of the quantum dot QD may be, for example, a polygonal cross-sectional shape, a rod-shaped three-dimensional shape, a branch-shaped three-dimensional shape, or a three-dimensional shape having unevenness on the surface thereof, or a combination of them.

The quantum dot QD may be typically made of a semiconductor. The semiconductor may have a constant band gap. The semiconductor may be a material capable of emitting light and may include at least a material which will be described below. The semiconductor may emit each of red light, green light, and blue light. The semiconductor includes, for example, at least one kind selected from the group consisting of a group II-VI compound, a group III-V compound, and a chalcogenide and a perovskite compound. Note that the group II-VI compound refers to a compound including a group II element and a group VI element, and the group III-V compound refers to a compound including a group III element and a group V element. The group II element may include a group 2 element and a group 12 element, the group III element may include a group 3 element and a group 13 element, the group V element may include a group 5 element and a group 15 element, and the group VI element may include a group 6 element and a group 16 element.

Examples of the group II-VI compound include at least one kind selected from the group consisting of MgS, MgSe, MgTe, CaS, CaSe, CaTe, SrS, SrSe, SrTe, BaS, BaSe, BaTe, ZnS, ZnSe, ZnTe, CdS, CdSe, CdTe, HgS, HgSe, and HgTe.

Examples of the group III-V compound include at least one kind selected from the group consisting of GaAs, GaP, InN, InAs, InP, and InSb.

The chalcogenide is a compound including a group VI A (16) element, and includes, for example, CdS or CdSe. The chalcogenide may include a mixed crystal thereof.

The perovskite compound has, for example, a composition represented by a general formula CsPbX₃. Examples of the constituent element X include at least one kind selected from the group consisting of Cl, Br, and I.

Here, the numbering of groups of an element by using Roman numerals is numbering based on the old International Union of Pure and Applied Chemistry (IUPAC) system or old Chemical Abstracts Service (CAS) system, and the numbering of groups of an element by using Arabic numerals is numbering based on the current IUPAC system.

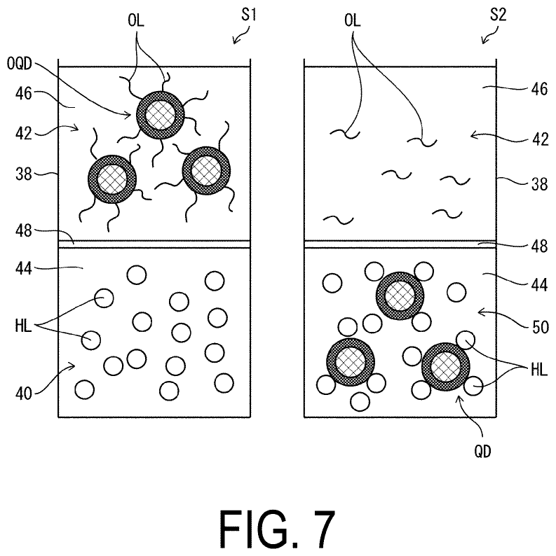

FIG. 7 is a diagram for explaining an example of a step of introducing halogen ligands HL with respect to the quantum dots QD included in the first portion 8a of the light-emitting layer 8 provided in the light-emitting element 1 according to the first embodiment.

In an S1 step illustrated in FIG. 7, first, a solution 40, in which the halogen ligands HL are dissolved, and a solution 42, in which quantum dots OQD with organic ligands OL coordinated thereto are dispersed, are injected into a container 38. The solution 40 includes a first solvent 44, in which the halogen ligand HL is soluble, and the solution 42 includes a solvent 46, in which the organic ligand OL is soluble. For example, the solvent 46 has a different polarity from that of the first solvent 44 and has a lower specific gravity than that of the first solvent 44. In order to more clearly distinguish a boundary between the solution 40 and the solution 42, a separation liquid 48 having specific gravity and polarity between those of the first solvent 44 and the solvent 46 may be injected into the container 38.

The first solvent 44 may include, for example, at least one kind selected from the group consisting of dimethyl sulfoxide (DMSO), N,N-dimethylformamide (DMF), N-methylformamide (NMF), formamide, N, N′-dimethylpropyleneurea, dimethylacetamide, N-methylpyrrolidone, gamma-butyrolactone, propylene carbonate, acetonitrile, 2-methoxyethanol, methyl acetate, ethyl acetate, ethyl formate, methyl formate, tetrahydrofuran, diethyl ether, tetrahydrothiophene, and diethyl sulfide. In this case, the first solvent 44 sufficiently disperses both the quantum dots QD with the coordinated halogen ligands HL, and a precursor 17P of the first material 17 to be described later. The first solvent 44 may be a polar solvent having a larger polarity than that of the solvent 46. The first solvent 44 may be prepared, for example, by dispersing zinc chloride, sodium chloride, or hydrochloric acid, in NMF, DMF, or DMSO. The solvent 46 is desired to be, for example, toluene, hexane, octane, or octadecene. To rephrase, the solvent 46 is desirably a non-polar solvent that is immiscible with the first solvent 44.

The organic ligand OL may be a ligand including a carbon chain that is generally used as a ligand of the quantum dot. The solvent 46 is a solvent in which the organic ligand OL is soluble, and therefore the quantum dot OQD with the organic ligand OL coordinated thereto is easily dispersed in the solution 42. In the solution 40, the halogen ligands HL are dissolved in an excessive amount exceeding the amount of the halogen ligands HL capable of being coordinated with the quantum dots. The concentration of the halogen ligands HL in the solution 40 is desirably 0.01 mol/l or more, and more desirably 0.1 mol/l or more.

In an S2 step illustrated in FIG. 7, that is, in a step of substituting the ligand of the quantum dot, the container 38 containing the solution 40 and solution 42 described above is vibrated at high speed by a stirrer to stir the solution 40 and the solution 42. To improve stirring efficiency, a stirring bar may be put into the container 38. In other words, the step of stirring the solution 40 and the solution 42 is a step of treating the quantum dots with the halogen ligands HL, in particular, a step of generating the quantum dots QD with the coordinated halogen ligands HL.

Here, as described above, the solution 40 contains an excessive amount of the halogen ligands HL. In general, when two or more kinds of ligands are contained in a solution in which quantum dots are dispersed, the ligands to be coordinated with the quantum dots are in an equilibrium state between the ligands in the solution. Thus, when the solution 40 and the solution 42 are stirred, at least some of the ligands coordinated with the quantum dots are substituted from the organic ligands OL to the halogen ligands HL.

For example, in the S2 step illustrated in FIG. 7, the solutions in the container 38 are stirred for at least one minute. The stirring of the solutions in the container 38 may be carried out at a frequency of 10 times per minute for one hour with the temperature of the solutions in the container 38 being set at 25° C. Under such conditions, it can be said that the probability that the ligands coordinated with the quantum dots in the container 38 are substituted with the halogen ligands HL is sufficiently high. In addition, to prevent water, oxygen, or the like in the air from being mixed with the solutions in the container 38, it is more desirable for the solutions in the container 38 to be stirred in an atmosphere of nitrogen, argon, or the like.

Accordingly, by carrying out the stirring discussed above, as illustrated in the S2 step of FIG. 7, a solution 50, in which the quantum dots QD with the coordinated halogen ligands HL are dispersed in the first solvent 44, and the solution 42, in which the organic ligands OL are dissolved in the solvent 46, are obtained in the container 38. As described above, the quantum dots QD, with which the halogen ligands HL are coordinated, can be obtained in the solution 50. The above-described stirring may be completed when the liquid in the container 38 is irradiated with ultraviolet light or the like and it is confirmed that the liquid layer emitting light has moved from the upper side to the lower side of the container 38.

In the S2 step illustrated in FIG. 7, that is, in the step of substituting the ligands of the quantum dots, the ligands of the quantum dots may be substituted so as to cause some of the organic ligands OL to remain in such a manner that the organic ligands OL included in the light-emitting layer 8 is preferably 15% or less by weight percent, and more preferably 10% or less by weight percent.

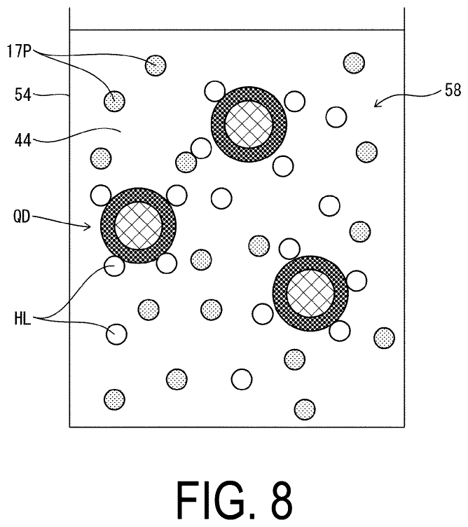

FIG. 8 is a diagram illustrating a first solution 58 used in a step of forming the first portion 8a of the light-emitting layer 8 provided in the light-emitting element 1 according to the first embodiment.

As illustrated in FIG. 8, prepared next is the first solution 58, which is a quantum dot dispersion liquid in which the quantum dots QD with the coordinated halogen ligands HL described above are dispersed. For example, only the solution 50 is extracted first from the container 38 illustrated in the S2 step of FIG. 7 discussed above by a dropper or the like, and then is injected into a container 54 illustrated in FIG. 8.

Here, a solution in which the precursor 17P of the first material 17 is dispersed in the first solvent 44 may be injected in advance into the container 38. Thus, as illustrated in FIG. 8, the first solution 58, which is a quantum dot dispersion liquid in which the quantum dots QD with the coordinated halogen ligands HL and the precursor 17P of the first material 17 are dispersed in the first solvent 44, is obtained in the container 54.

In the present embodiment, the precursor 17P of the first material 17 contained in the first solution 58 as the quantum dot dispersion liquid is a precursor of a metal sulfide, and may include, for example, at least one of a metal acetate, a metal nitrate and a metal halide salt as a metal source, and at least one of thiourea, N-methylthiourea, 1,3-dimethylthiourea, N, N′-dimethylthiourea, tetramethylthiourea and thioacetamide as a sulfur source. Alternatively, the precursor of the metal sulfide may include a metal complex in which thiourea, N-methylthiourea, 1, 3-dimethylthiourea, N, N′-dimethylthiourea, tetramethylthiourea, or thioacetamide is coordinated with a metal atom.

A method for forming the light-emitting layer 8 provided in the light-emitting element 1 according to the present embodiment includes: a step of forming the first portion 8a of the light-emitting layer 8 by using the first liquid 58 (illustrated in FIG. 8) containing the precursor 17P of the first material 17 forming the inorganic matrix of the first material 17, the quantum dots QD different from the first material 17, and the first solvent 44; and a step of forming the second portion 8b of the light-emitting layer 8 by using a second solution (not illustrated) containing a precursor of the second material 18 forming the inorganic matrix of the second material 18 different from the third material, the quantum dots QD, and a second solvent. In the present embodiment, since the first material 17 and the second material 18 are the same material, the precursor of the second material 18 is the same precursor as the precursor 17P of the first material 17. For example, a precursor of a metal sulfide may be used, and the second solvent may use the same solvent as the first solvent 44. The number of quantum dots QD contained per unit volume of the second solution is 0 or more and less than the number of quantum dots QD contained per unit volume of the first solution 58.

In the present embodiment, as described above, since the second portion 8b of the light-emitting layer 8 includes the quantum dots QD, the second solution contains one or more quantum dots QD, and the number of quantum dots QD contained per unit volume of the first solution 58 is larger than the number of quantum dots contained per unit volume of the second solution. Without being limited thereto, in a case where the second portion 8b of the light-emitting layer 8 does not include any quantum dot QD as in a second embodiment to be described later, the number of quantum dots QD contained in the second solution may be 0.

In the present embodiment, as discussed above, since the second portion 8b of the light-emitting layer 8 includes the quantum dots QD, the case where both the first solution 58 and the second solution contain the ligands has been described as an example. However, the disclosure is not limited thereto, and only the first solution 58 may contain the ligands when the second portion 8b of the light-emitting layer 8 does not include any quantum dot QD as in the second embodiment to be described later.

In the present embodiment, as illustrated in FIG. 1, the light-emitting element 1 will be described exemplifying a light-emitting element of a sequentially layered structure in which there are included the anode 22 and the cathode 25 provided above the anode 22, and the hole transport layer 7, the first portion 8a of the light-emitting layer 8, the second portion 8b of the light-emitting layer 8, and the electron transport layer 9 are layered in this order from the anode 22 side, for example, between the anode 22 and the cathode 25. However, the disclosure is not limited thereto. For example, the light-emitting element 1 may be a light-emitting element of an inversely layered structure. In the case of the light-emitting element of the inversely layered structure, although not illustrated, there are included the cathode 25 and the anode 22 provided above the cathode 25, and between the cathode 25 and the anode 22, for example, the electron transport layer 9, the second portion 8b of the light-emitting layer 8, the first portion 8a of the light-emitting layer 8, and the hole transport layer 7 are layered in this order from the cathode 25 side.

The light-emitting element 1 may be a top-emitting type or a bottom-emitting type. When the light-emitting element of the sequentially layered structure is intended to be a top-emitting type, it is sufficient that the anode 22 is formed of an electrode material that reflects visible light, and the cathode 25 is formed of an electrode material that transmits visible light. When the light-emitting element of the sequentially layered structure is intended to be a bottom-emitting type, it is sufficient that the anode 22 is formed of an electrode material that transmits visible light, and the cathode 25 is formed of an electrode material that reflects visible light. On the other hand, when the light-emitting element of the inversely layered structure is intended to be a top-emitting type, it is sufficient that the cathode 25 is formed of an electrode material that reflects visible light, and the anode 22 provided above the cathode 25 is formed of an electrode material that transmits visible light. When the light-emitting element of the inversely layered structure is intended to be a bottom-emitting type, it is sufficient that the cathode 25 is formed of an electrode material that transmits visible light, and the anode 22 provided above the cathode 25 is formed of an electrode material that reflects visible light.

The electrode material that reflects visible light is not particularly limited as long as the material can reflect visible light and has electrical conductivity, and examples thereof include metal materials such as Al, Mg, Li, and Ag, alloys of the metal materials, a layered body of the metal materials and transparent metal oxides (for example, indium tin oxide, indium zinc oxide, indium gallium zinc oxide, and the like), or a layered body of the alloys and the transparent metal oxides.

On the other hand, the electrode material that allows visible light to pass through is not particularly limited as long as the material can allow visible light to pass through and has electrical conductivity, and examples thereof include a thin film formed of a transparent metal oxide (for example, indium tin oxide, indium zinc oxide, indium gallium zinc oxide, and the like) or a metal material such as Al and Ag, or a nano wire formed of a metal material such as Al and Ag.

As described above, according to the above-described method for forming the light-emitting element 1 or the light-emitting layer 8, the external quantum efficiency (EQE), the carrier balancing, and the reliability may be improved.

### Second Embodiment

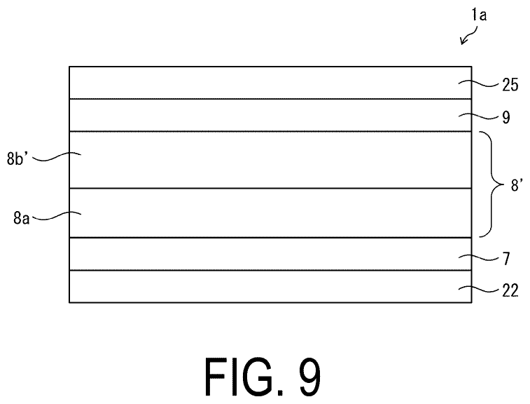

Next, the second embodiment of the disclosure will be described with reference to FIGS. 9 to 11. A light-emitting element la of the present embodiment is different from the light-emitting element 1 described in the first embodiment in that a second portion 8b′ of a light-emitting layer 8′ provided in the light-emitting element 1a includes no quantum dot QD and is formed of an inorganic matrix of a second material 18. The other details are as described in the first embodiment. For convenience of description, members having the same functions as those shown in the drawings according to the first embodiment are denoted by the same reference numerals and signs, and descriptions thereof will be omitted.

FIG. 9 is a cross-sectional view illustrating a schematic configuration of the light-emitting element 1a according to the second embodiment.

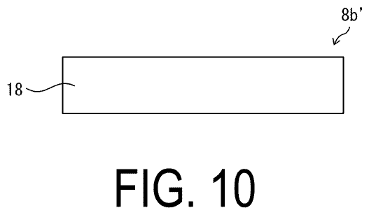

FIG. 10 is a cross-sectional view of the second portion 8b′ provided in the light-emitting element 1a according to the second embodiment.

As illustrated in FIG. 9, the light-emitting element 1a includes an anode 22, a cathode 25, and the light-emitting layer 8′ provided between the anode 22 and the cathode 25.

The light-emitting layer 8′ includes a first portion 8a including quantum dots QD and an inorganic matrix of a first material 17 as illustrated in FIG. 2, and the second portion 8b′ including no quantum dot QD and formed of the inorganic matrix of the second material 18 as illustrated in FIG. 10. The first portion 8a is provided closer to the anode 22 than the second portion 8b′. That is, the filling rate of the quantum dots QD in the cross section of the second portion 8b′ is 0%. In the present embodiment, the inorganic matrix of the second material 18 does not include the quantum dot QD, but may be composed of a substance capable of holding the quantum dots QD or the like, or may be composed of the same substance as the substance constituting the first material 17. The second portion 8b′ does not include the quantum dot QD, but may be composed of a substance capable of holding the quantum dots QD or the like, or may be composed of the same substance as the substance constituting the first portion 8a.

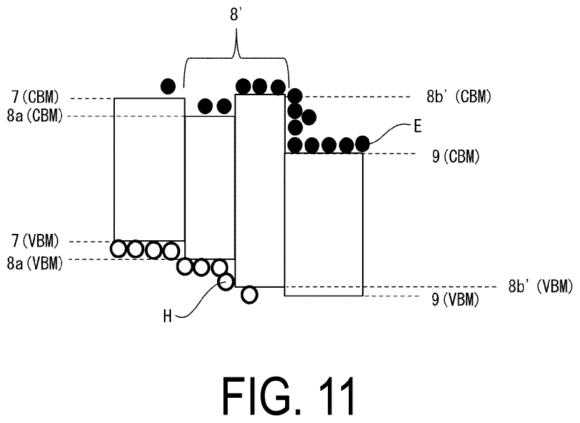

FIG. 11 is a diagram illustrating band levels of a hole transport layer 7, the light-emitting layer 8′, and an electron transport layer 9, which are provided in the light-emitting element 1a according to the second embodiment.

In the present embodiment, a case where the band gap of the first material 17 and the band gap of the second material 18 are larger than the band gap of the quantum dot QD will be described as an example, but the disclosure is not limited thereto, and the band gap of the first material 17 and the band gap of the second material 18 may be equal to or larger than the band gap of the third material included in the quantum dot QD.

As described above, in the case where the band gap of the first material 17 and the band gap of the second material 18 are larger than the band gap of the quantum dot QD and when the filling rate of the quantum dots QD in the cross section of the first portion 8a of the light-emitting layer 8′ is larger than the filling rate of the quantum dots QD in the cross section of the second portion 8b′ of the light-emitting layer 8′, it can be schematically represented that the valence band maximum (VBM) of the second portion 8b′ is deeper than the valence band maximum (VBM) of the first portion 8a and the conduction band minimum (CBM) of the second portion 8b′ is shallower than the conduction band minimum (CBM) of the first portion 8a as illustrated in FIG. 11. In addition, the valence band maximum (VBM) and the conduction band minimum (CBM) of the second portion 8b′ can be schematically represented in such a manner that the valence band maximum (VBM) is deeper and the conduction band minimum (CBM) is shallower than the valence band maximum (VBM) and the conduction band minimum (CBM) of the second portion 8b of the first embodiment. In the light-emitting element 1a as discussed above, since the injection barrier of electrons E into the light-emitting layer 8′ can be made higher while suppressing a situation in which the injection barrier of holes H into the light-emitting layer 8′ becomes high, the injection of the electrons E into the light-emitting layer 8′ is suppressed, and the overflow of the electrons E into the hole transport layer 7 can be further reduced. Accordingly, the life of the light-emitting element 1a can be further extended and the reliability of the light-emitting element 1a can be improved.

Each of the first material 17 and the second material 18 included in the light-emitting layer 8′ provided in the light-emitting element 1a according to the present embodiment may be a metal sulfide. In the present embodiment, a case where the first material 17 and the second material 18 are made of the same metal sulfide (e.g., ZnS) will be described as an example, but the disclosure is not limited thereto, and the first material 17 and the second material 18 may be different metal sulfides.

In the present embodiment, as compared with the case of the organic ligand discussed above, an inorganic ligand as a material having high carrier mobility such as a halogen ligand containing a halogen atom, and the first material 17 and second material 18 formed of ZnS are used. This makes it possible to reduce a reactive current flowing through in the light-emitting layer 8′ and achieve the light-emitting element 1a with the improved external quantum efficiency (EQE).

In general, in a light-emitting element including an anode for supplying holes, a cathode for supplying electrons, and a light-emitting layer, the carrier balancing is often poor because the electron mobility is higher than the hole mobility. In the light-emitting element 1a according to the present embodiment, as described above, the filling rate of the quantum dots QD in the cross section of the first portion 8a of the light-emitting layer 8′ is higher than the filling rate of the quantum dots QD in the cross section of the second portion 8b′ of the light-emitting layer 8′, and thus the concentration of the quantum dots QD in the first portion 8a of the light-emitting layer 8′ is higher than the concentration of the quantum dots QD in the second portion 8b′ of the light-emitting layer 8′. Accordingly, a large number of holes supplied from the anode 22 through the hole transport layer 7 are trapped by a larger number of quantum dots QD contained in the first portion 8a of the light-emitting layer 8′ located closer to the anode 22. On the other hand, a large number of electrons supplied from the cathode 25 through the electron transport layer 9 are also trapped by the larger number of quantum dots QD contained in the first portion 8a of the light-emitting layer 8′ located farther from the cathode 25. Thus, it is possible to more effectively improve imbalance in mobility such as the mobility of electrons being higher than the mobility of holes.

In addition, in the present embodiment, as described above, since the second portion 8b′ of the light-emitting layer 8′ does not include the quantum dot QD, it is unnecessary for the second portion 8b′ of the light-emitting layer 8′ to include a ligand including an organic ligand, thereby making it possible to achieve the light-emitting element 1a with the improved reliability.

As described thus far, according to the light-emitting element 1a, the external quantum efficiency (EQE), carrier balancing, and reliability can be improved.

### Third Embodiment

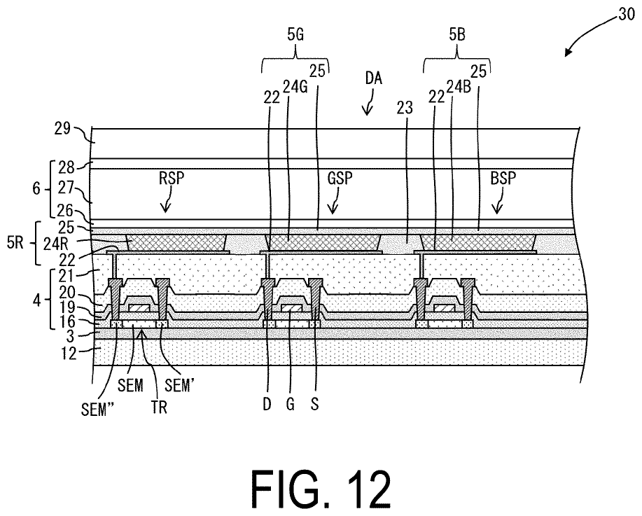

Next, a third embodiment of the disclosure will be described with reference to FIG. 12. A display device 30 according to the present embodiment is different from those of the first end second embodiments in that it is a display device including the light-emitting elements 1 and 1a. The other details are as described in the first and second embodiments. For convenience of description, members having the same functions as those shown in the drawings according to the first and second embodiments are denoted by the same reference numerals and signs, and descriptions thereof will be omitted.

FIG. 12 is a cross-sectional view illustrating a schematic configuration of the display device 30 according to the third embodiment.

As illustrated in FIG. 12, a red subpixel RSP of the display device 30 includes a red light-emitting element 5R, a green subpixel GSP of the display device 30 includes a green light-emitting element 5G, and a blue subpixel BSP of the display device 30 includes a blue light-emitting element 5B.

In the present embodiment, the red light-emitting element 5R including a function layer 24R having a red light-emitting layer is the light-emitting element 1 described in the first embodiment or the light-emitting element 1a described in the second embodiment, the green light-emitting element 5G including a function layer 24G having a green light-emitting layer has the same configuration as the light-emitting element 1 described in the first embodiment or the light-emitting element 1a described in the second embodiment except that the quantum dot that emits green light is used, and the blue light-emitting element 5B including a function layer 24B having a blue light-emitting layer has the same configuration as the light-emitting element 1 described in the first embodiment or the light-emitting element 1a described in the second embodiment except that the quantum dot that emits blue light is used. Without being limited thereto, for example, among the red light-emitting element 5R, the green light-emitting element 5G, and the blue light-emitting element 5B, only the red light-emitting element 5R may be the light-emitting element 1 described in the first embodiment or the light-emitting element 1a described in the second embodiment.

As illustrated in FIG. 12, in a display region DA of the display device 30, a barrier layer 3, a thin film transistor layer 4 including transistors TR, the red light-emitting element 5R, the green light-emitting element 5G, the blue light-emitting element 5B, a bank 23, a sealing layer 6, and a function film 29 are provided on a substrate 12 in this order from the substrate 12 side.

The substrate 12 may be, for example, a resin substrate made of a resin material such as a polyimide, or may be a glass substrate. In the present embodiment, the display device 30 is a flexible display device, and thus a case will be described as an example in which a resin substrate made of a resin material such as a polyimide is used as the substrate 12; however, the disclosure is not limited thereto. In a case where the display device 30 is a non-flexible display device, a glass substrate may be used as the substrate 12.

The barrier layer 3 is a layer that inhibits foreign matter, such as water and oxygen, from entering the transistor TR, the red light-emitting element 5R, the green light-emitting element 5G, and the blue light-emitting element 5B, and can be formed of, for example, a silicon oxide film, a silicon nitride film, or a silicon oxynitride film, or a layered film thereof formed by using a chemical vapor deposition (CVD) method.

A transistor TR portion of the thin film transistor layer 4 including the transistor TR includes a semiconductor film SEM, doped semiconductor films SEM′ and SEM″, an inorganic insulating film 16, a gate electrode G, an inorganic insulating film 19, an inorganic insulating film 20, a source electrode S, a drain electrode D, and a flattening film 21. A portion other than the transistor TR portion of the thin film transistor layer 4 including the transistor TR includes the inorganic insulating film 16, the inorganic insulating film 19, the inorganic insulating film 20, and the flattening film 21.

The semiconductor films SEM, SEM′ and SEM″ may be formed of low-temperature polysilicon (LTPS) or an oxide semiconductor (for example, an In—Ga—Zn—O based semiconductor), for example. Although a case in which the transistor TR has a top gate structure is exemplified in the present embodiment, the disclosure is not limited thereto, and the transistor TR may have a bottom gate structure.

The gate electrode G, the source electrode S, and the drain electrode D may be formed of a single-layer film or a layered film of a metal including, for example, at least one of aluminum, tungsten, molybdenum, tantalum, chromium, titanium, and copper.

The inorganic insulating film 16, the inorganic insulating film 19, and the inorganic insulating film 20 can be formed of, for example, a silicon oxide film, a silicon nitride film, or a silicon oxynitride film, or a layered film thereof, formed by using the CVD method.

The flattening film 21 can be formed of a coatable organic material such as a polyimide or acrylic, but may be formed of an inorganic film.

The red light-emitting element 5R included in the red subpixel RSP includes an anode 22 provided above the flattening film 21, the function layer 24R including the red light-emitting layer, and a cathode 25; the green light-emitting element 5G included in the green subpixel GSP includes the anode 22 provided above the flattening film 21, the function layer 24G including the green light-emitting layer, and the cathode 25; and the blue light-emitting element 5B included in the blue subpixel BSP includes the anode 22 provided above the flattening film 21, the function layer 24B including the blue light-emitting layer, and the cathode 25. The bank 23 with insulating properties covering the edge of the anode 22 can be formed, for example, by applying an organic material such as polyimide or acrylic, and then patterning the applied organic material by photolithography, but may be formed of an inorganic film.

As described thus far, according to the display device 30, the external quantum efficiency (EQE), carrier balancing, and reliability can be improved.

### APPENDIX

The disclosure is not limited to the embodiments described above, and various modifications may be made within the scope of the claims. Embodiments obtained by appropriately combining technical approaches disclosed in the different embodiments also fall within the technical scope of the disclosure. Furthermore, novel technical features can be formed by combining the technical approaches disclosed in each of the embodiments.

### INDUSTRIAL APPLICABILITY

The disclosure may be utilized in methods for forming light-emitting elements, display devices, and light-emitting layers.

### REFERENCE SIGNS LIST

1, 1a Light-emitting element
5R Red light-emitting element (light-emitting element)
5G Green light-emitting element (light-emitting element)
5B Blue light-emitting element (light-emitting element)
7 Hole transport layer
8, 8′ Light-emitting layer
8a First portion
8b, 8b′ Second portion
9 Electron transport layer
17 First material (inorganic matrix)
17P Precursor of first material
18 Second material (inorganic matrix)
22 Anode
24R Function layer including red light-emitting layer
24G Function layer including green light-emitting layer
24B Function layer including blue light-emitting layer
25 Cathode
30 Display device
44 First solvent
58 First solution
QD Quantum dot
OQD Quantum dot including organic ligand
OL Organic ligand
HL Halogen ligand
CBM Conduction band minimum
VBM Valence band maximum
E Electron
H Hole
RSP Red subpixel
GSP Green subpixel
BSP Blue subpixel
DA Display region

1. A light-emitting element, comprising:
an anode;
a cathode; and
a light-emitting layer including a plurality of quantum dots provided between the anode and the cathode,
wherein the light-emitting layer includes a first portion including an inorganic matrix of a first material, which is different from the plurality of quantum dots, and a second portion including an inorganic matrix of a second material, which is different from the plurality of quantum dots,
the first portion is provided closer to the anode than the second portion,
filling with at least the inorganic matrix of the first material is made between the plurality of quantum dots, and
a filling rate of the plurality of quantum dots in a cross section of the first portion is greater than a filling rate of the plurality of quantum dots in a cross section of the second portion.

2. The light-emitting element according to claim 1,
wherein the second portion includes the plurality of quantum dots.

3. The light-emitting element according to claim 2,
wherein the filling rate of the second portion is less than 30%.

4. The light-emitting element according to claim 3,
wherein the filling rate of the second portion is equal to or less than 20%.

5. The light-emitting element according to claim 1,
wherein the second portion is formed of the inorganic matrix of the second material.

6. The light-emitting element according to claim 5,
wherein the filling rate of the second portion is 0%.

7. The light-emitting element according to claim 1,
wherein the filling rate of the first portion is in a range from 30% to 91%.

8. The light-emitting element according to claim 1,
wherein a difference between the filling rate of the first portion and the filling rate of the second portion is in a range from 10% to 91%.

9. The light-emitting element according to claim 1,
wherein the quantum dot includes a core and a shell,
the shell includes the first material or the second material, and
the core is different from the first material and the second material.

10. The light-emitting element according to claim 1,
wherein a band gap of the first material and a band gap of the second material are equal to or greater than a band gap of the third material.

11. The light-emitting element according to claim 1,
wherein the plurality of quantum dots include an element of a first kind, and
each of the first material and the second material includes an element of a second kind that is higher by one or more periods than the element of the first kind.

12. The light-emitting element according to claim 1,
wherein the first material and the second material are each formed of a metal sulfide.

13. The light-emitting element according to claim 12,
wherein the first material is formed of a first metal sulfide,
the second material is formed of a second metal sulfide,
the first metal sulfide is formed of zinc (Zn) and sulfur (S), formed of zinc (Zn), tellurium (Te), and sulfur (S), formed of zinc (Zn), magnesium (Mg), and sulfur (S), formed of magnesium (Mg) and sulfur (S), formed of gallium (Ga) and sulfur (S), or formed of magnesium (Mg), gallium (Ga), and sulfur (S), and
the second metal sulfide is different from the first metal sulfide.

14. The light-emitting element according to claim 12,
wherein the first material and the second material are each formed of the same metal sulfide, and
the same metal sulfide is formed of zinc (Zn) and sulfur (S), formed of zinc (Zn), tellurium (Te), and sulfur (S), formed of zinc (Zn), magnesium (Mg), and sulfur (S), formed of magnesium (Mg) and sulfur (S), formed of gallium (Ga) and sulfur (S), or formed of magnesium (Mg), gallium (Ga), and sulfur (S).

15. The light-emitting element according to claim 1,
wherein the light-emitting layer includes an inorganic ligand.

16. The light-emitting element according to claim 15,
wherein the inorganic ligand includes a halogen atom.

17. The light-emitting element according to claim 1,
wherein the light-emitting layer includes an organic ligand, and
in a case where A is weight of the organic ligands measured by thermogravimetry, and B is weight of the light-emitting layer measured by the thermogravimetry, a value of (A/B)×100% is equal to or less than 10%.

18. The light-emitting element according to claim 1,
wherein a hole function layer is provided between the anode and the first portion, and
an electron function layer is provided between the cathode and the second portion.

19. The light-emitting element according to claim 18,
wherein the hole function layer includes at least one of a hole transport layer and a hole injection layer, and
the electron function layer includes at least one of an electron transport layer and an electron injection layer.

20. A display device comprising:
the light-emitting element according to claim 1.

21-25. (canceled)
